(19) United States
(12) Patent Application Publication
(10) Pub. No.: US 2026/0186043 A1
(43) Pub. Date: Jul. 2, 2026

(54) METHOD FOR ONE-STEP AGING SIMULATION OF A TRANSISTOR DYNAMICALLY STRESSED DURING OPERATION

(71) Applicant: Wallace W Lin, San Jose, CA (US)

(72) Inventor: Wallace W Lin, San Jose, CA (US)

(21) Appl. No.: 19/092,128

(22) Filed: Mar. 27, 2025

Related U.S. Application Data
(60) Provisional application No. 63/739,201, filed on Dec. 27, 2024.

(51) Int. Cl. G01R 31/26; G01R 31/3183

(52) U.S. Cl. CPC G01R 31/2642; G01R 31/318357

(57) ABSTRACT

A method for aging simulation of transistors is disclosed. The method is based on a derived general aging model that is conformed to the natural physical aging behavior of transistors and take into account interaction between the accumulated aging effect and its induced characteristics change of transistors dynamically stressed during operation.

### CROSS-REFERENCE TO RELATED APPLICATION

This application claims the benefit of U.S. Provisional Application No. 63/739,201, filed on Dec. 27, 2024.

### BACKGROUND

### 1. Technical Field

The present disclosure is directed to a method that enables a one-step transistor aging simulation taking into account interaction between accumulated aging induced characteristics change of transistors stressed dynamically during operation.

### 2. Description of Related Art

Existing circuit aging simulations in the industry carry fundamental drawbacks in terms of its methodology and application. One most notable drawback is the use of a non-physical trend such as a linear one or an uncalibrated nonlinear one in simulations. A linear-extrapolation based circuit aging simulation overestimates aging effect for transistors and hence circuits. On the other hand, the use of multiple time steps in simulation in an effort to catch and make up the effect of accumulated aging induced change on transistor characteristics and in turn the change of the transistor model parameters at these time steps is a nice idea. However, such idea is ruined by the use of inappropriate aging scaling means, yielding misleading aging simulation result at the end.

Similar to the tactic of using short-term physical stress to circuit components or circuit itself in order to accelerate the extraction of long-term circuit damage or lifetime, circuit aging simulation accelerates the estimation for long-term damage via short-term aging simulation. To dramatically reduce the physical stress time is the motive behind the former. Similar motive for greatly cutting down the simulation time is also behind the latter.

The aging effect or damage to the circuit components undergoing stress during circuit operation will change gradually the characteristics of the aging (i.e., damaging) mechanism of the components. This, as a result, would contribute to the extent of the new aging damage from a subsequent stress.

The damage continues to accumulate over time and continuously impacts the aging damaging mechanism characteristics and hence the damage result itself. Since it is extremely difficult to characterize and model accumulated aging induced change of transistor characteristics, this interaction between the accumulated aging damage and the aging damage mechanism is a fundamental issue faced by aging simulation of circuit components nowadays in the industry. How to accurately take into account such interaction effect and accurately predict the aging damage of circuit components is the main subject of this invention.

### SUMMARY

This disclosure presents a method based on a derived nature-manifested aging model in its simplest and pristine form in which the aging mechanism is let go naturally without constraint during aging simulation of transistors. Such relaxation technique requires rigidly the natural behavior of the aging model describing the aging mechanism. The let-go relaxation together with the disclosed innovated “Forge & Anneal” technique naturally leads the aging mechanism to settling into a rest state where accurate extraction of the two key parameters of the aging model, the beginning aging rate and the steady-state aging damage, are achieved. The invention here provides a way to overcome the hurdle of confidently and reliably estimate transistor and circuit aging since the debut of the transistor aging model in industry several decades ago.

The invented aging simulation method takes into account electronic component wear-out effect as well as continuously accumulated aging effect. As a result, it accomplishes the one long-standing goal in the industry to enable an one-step aging simulation for electronic components and circuit to any specified operating time.

For further understanding of the present disclosure, reference is made to the following detailed description illustrating the embodiments and examples of the present disclosure. The description is only for illustrating the present disclosure, not for limiting the scope of the claim.

### BRIEF DESCRIPTION OF THE DRAWINGS

The drawings included herein provide further understanding of the present disclosure. A brief introduction of the drawings is as follows:

FIG. 1 illustrates a time-line chart of circuit aging simulation according to one embodiment of the present disclosure;

FIG. 2 shows a flowchart for an overview of the invented transistor aging simulation method according to one embodiment of the present disclosure;

FIG. 3 shows a flowchart of how to generate a correlation table which correlates transistor accumulated aging damage to transistor characteristics change induced aging damage according to one embodiment of the present disclosure;

FIG. 4 shows a scatter plot of the elements in the Correlation Table used in obtaining result in FIG. 8 according to one embodiment of the present disclosure;

FIG. 5 shows a flowchart of “Forge & Anneal” technique in one-transistor case to extract naturally-settled initial aging rate and final saturated aging damage of a transistor during aging simulation according to one embodiment of the present disclosure;

FIG. 6 illustrates the “Forge & Anneal” process in terms of time-line chart according to one embodiment of the present disclosure;

FIG. 7 illustrate the “Forge & Anneal” process in terms of segments of the accumulated aging damage versus operating time according to one embodiment of the present disclosure;

FIG. 8 shows the evolution of the aging damage curve on one transistor in a circuit during “Forge & Anneal” process according to one embodiment of the present disclosure;

FIG. 9 is the nonlinear least-squares fitting result in one of the “Forge & Anneal” iteration cycles, showing excellent fitting;

FIG. 10(a) shows how the initial aging rate (r) evolves during “Forge & Anneal” process according to one embodiment of the present disclosure;

FIG. 10(b) shows how the final saturated aging damage (k) evolves during “Forge & Anneal” process according to one embodiment of the present disclosure; and

FIG. 11 shows the evolution of the aging damage curve on one of the other nine transistors in a circuit during “Forge & Anneal” process according to one embodiment of the present disclosure.

### DESCRIPTION OF THE EXEMPLARY EMBODIMENTS

The aforementioned and other technical contents, features, and efficacies will be shown in the following detailed descriptions of embodiments corresponding with the reference figures.

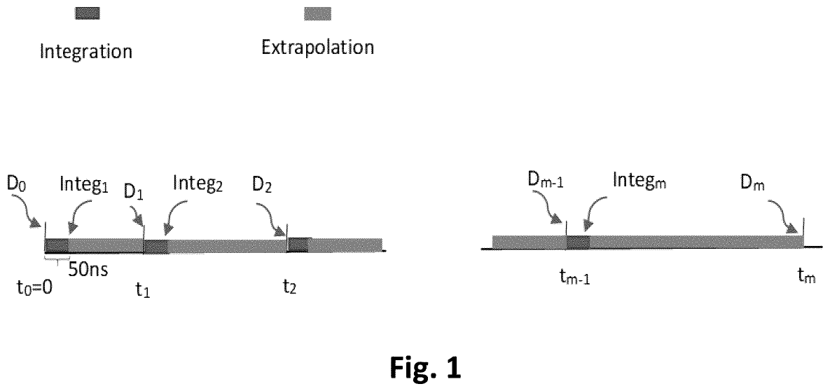

FIG. 1 illustrates a time-line chart of circuit aging simulation. The horizontal darker-color bar denotes the duration of the short-term aging simulation while the lighter-color bar the duration of the longer- or long-term aging simulation. Each time tick represents the beginning of the short-term aging simulation. There are m+1 time ticks from t₀ to tₘ, representing m multiple-step simulations. The reason of requiring short-term simulation is to reduce the total simulation time in each of the multiple-step simulations. The reason of requiring multiple-step simulations is to account for the accumulated aging damage induced transistor aging effect, which affects again subsequent simulation for accumulated aging damage, such that the overall simulation becomes more accurate.

The short- and longer-term simulation form one step of the m-step overall simulations. The dramatic cut of the simulation time in each of all m steps is achieved by scaling the short-term aging effect to long term. This cab be performed by either a linear scaling or by an uncalibrated nonlinear trend scaling. Both are non-physical and their scaling results inaccurate.

The aging effect or damage to the circuit components undergoing stress during circuit operation will change gradually the characteristics of the aging (i.e., damaging) mechanism of the components. This, as a result, would contribute to a further new aging damage from a subsequent stress. This interaction phenomenon can be explained at time tick tₘ₋₁ in FIG. 1. The m^{th} simulation step produces an accumulated aging damage of Dₘ which affects the aging mechanism and subsequently the aging damage in the next (m+1^{th}) simulation step, as described in Eqs. (1) and (2) below. The accumulated damage of Dₘ alters value of the characteristics parameters (ΔP_{i_Model}|ₘ) of circuit components. The altered circuit component characteristics in turn affect short-term aging damage in the m+1^{th} simulation step.

$$Δ {P}_{i \_ Model \vert m} = G ( {D}_{m} ) \qquad ( 1 )$$

$$Integ {\vert}_{m + 1} = f ( Δ {P}_{i \_ Model \vert m} = f ( G ( {D}_{m} ) ) \qquad ( 2 )$$

In reality, such phenomenon occurs at every moment continuously during the stress event, as expressed by Eq. (3).

$$Integ ( t ) = f ( Δ {P}_{i \_ Model} ( t ) ) = f ( G ( D ( t ) ) ) \qquad ( 3 )$$

The damage continues to accumulate over time and continuously impacts the aging damaging mechanism characteristics and hence the damage result itself. Since it is extremely difficult to characterize and model ΔP_{i_Model}(t), this interaction between the accumulated aging damage and the aging damage mechanism is a fundamental issue faced by aging simulation of circuit components nowadays in the industry. How to accurately take into account such interaction effect and accurately predict the aging damage of circuit components is the main purpose of this invention.

This invention aims at overcoming the above issues. A general aging model for transistors is derived first. The model fits the natural aging behavior of the circuit components such as transistors. A method is then devised and works with this general aging model to accurately simulate the accumulated damage induced aging effect for transistors and circuits. The model and the method are implemented in a C program. The program verifies the model and method with collected aging data of transistors.

### A. General Aging Model

For physical entities including circuit components, a nature-manifested aging model has to possess basic traits as follows. First, there must exist a force that triggers the aging process. Such force may exist at beginning or during part or whole period of the process. Second, the effect of the aging process is continuously accumulated over the period of the process with accumulated effect at every moment of the aging process. Third, a rate of aging is accompanied at every moment of the aging process. In order to be submissive to the simplest and pristine form of the mechanism of this kind, there should exist a minimum number of factors that define the behavior of the process. These factors are morphed into the boundary conditions in the simplest relations at the beginning and the end of the process.

Based on the above, the mechanism of a nature-oriented aging process is described in four simplest relations below:

$${lim}_{t = 0} D = {D}_{0} \qquad ( 4 )$$

$${lim}_{t = 0} \frac{dD}{dt} = r \qquad ( 5 )$$

$${lim}_{t = ∞} D = {D}_{∞} \qquad ( 6 )$$

$${lim}_{t = ∞} \frac{dD}{dt} = 0 \qquad ( 7 )$$

Eq. (4) states the state of aging right at beginning of the aging process where the aging effect or damage is D₀ which is usually zero before an aging force is applied. Eq. (5) states that the rate of aging is r at beginning of the process. r may be assumed to be linear given the linearization approximation in an infinitesimal time interval. Eq. (6) describes that after infinitely long time, the impact of the aging effect eventually approaches to a steady state (i.e., saturated), a constant of D_{∞}. Eq. (7) describes the rate of aging approaching to zero after infinitely long time. Eqs. (6) and (7) depict the “worn-out” phenomenon in nature where the entity experiencing the aging process gradually wears out such that the aging process eventually saturates.

Eqs. (4) to (7) can be solved. This gives rise to a solution—a formula for an aging model in its simplest and pristine form, as expressed in Eq. (8).

$$D ( t ) = {D}_{∞} - ( {D}_{∞} - {D}_{0} ) {e}^{- \frac{r}{{D}_{∞} ,} t} \qquad ( 8 )$$

On circuit components, Eqs. (4) and (5) describe that at the beginning moment before a circuit component such as a transistor experiences stress, the aging behavior appears to be linear with a rate of r given the linearization approximation in an infinitesimal time interval for a nonlinear damaging behavior. The accumulated aging or damaging effect value at t=0 before stress is a constant of D₀ which is usually zero. For electronic components, D₀ here refers to “Age” or “Damage”. As the aging effect accumulates, the transistor degrades as its threshold voltage increases and drive current decreases, leading to lesser and lesser damaging effect to the transistor as stress continues. The aging behavior eventually saturates. The aging rate reduces to 0 and the damage value saturates at a constant value of D_{∞} eventually, as described by Equations (6) and (7). For convenience purpose, D_{∞} is renamed to k here. As a result, Eq. (9) below represents the aging model in electronics case.

$$D ( t ) = k - ( k - {D}_{0} ) {e}^{- \frac{r}{k} t} \qquad ( 9 )$$

### B. Application of Aging Model

Huddles are faced to make use of the derived aging model here. Extracting the initial aging rate, r, and the steady-state or saturated aging damage, k, of the aging model from practical aging data appears to be nontrivial and unstraightforward. This is because initially there does not exist data that behave the real trend of the aging induced damage of electronic components such as a transistor because r and k has not been extracted yet. Such data must be built step by step gradually from scratch. One needs to come up with an initial guess of r and k from data grossly estimated initially. For example, one may use short-term data to obtain long-term data of transistor damage versus operating time by linearly extrapolating the short-term data to a time long after t=0. By LSF such data to Eq. (9), one is able to obtain a rough initial estimate for r and k. With this r and k value here, one begins to launch the process to be described below with a final goal of obtaining a true settled steady-state value of r and k.

First, one constructs a two-point data at t=t₁ and t=50 ns as shown in FIG. 1. The aging damage at t=50 ns, Integ1, is obtained via a linear integral of transistor aging in a very short 50 ns interval. From the two data points, (0, D₀) and (50 ns, Integ1), one calculates r₁. Using the calculated r₁ and the k value obtained earlier in the nonlinear LSF, the aging effect is then extended to t=t₁ to obtain damage occurred during (t₀, t₁) duration with the following formula derived from Eq. (9):

$${D}_{1} = k - ( k - {D}_{0} ) {e}^{- \frac{{r}_{1}}{k} ( {t}_{1} - {t}_{0} )} \qquad ( 10 )$$

To account for the continuously accumulated aging damage, the circuit simulator will update transistor model parameter values at the accumulated damage of D₁ to calculate the linear aging integral over the 50 ns interval, Integ₂. Further, an aging rate of r₂ can be calculated based on Integ₂. The aging effect is then extended to t=t₂ to obtain damage D₂ there by following the formula below:

$${D}_{2} = k - [ k - {D}_{1} ) ] {e}^{- \frac{{r}_{2}}{k} ( {t}_{2} - {t}_{1} )} \qquad ( 11 )$$

Note that k value obtained from the nonlinear LSF previously is used throughout this process. The above process can be repeated to obtain D₃, D₄, . . . , Dₘ₋₁, Dₘ by following Eq. (12) below:

$${D}_{m} = k - [ k - {D}_{m - 1} ) ] {e}^{- \frac{{r}_{m}}{k} ( {t}_{m} - {t}_{m - 1} )} \qquad ( 12 )$$

tₘ is a time point for long-term aging simulation. Up to this point, one is able to construct data with m+1 points from time zero to tₘ. These m+1 data points provide an opportunity to extract a supposedly improved aging rate, r, and saturated aging damage, k. The extraction can be carried out with a non-linear least-squares fitting to the m+1 data points using Eq. (9).

The above “Forge” process of building D₁ to Dₘ and the “Anneal” process of nonlinear LSF to the assembled data of D₁ to Dₘ for extracting improved r and k constitute one cycle of the “Forge & Anneal” process. Such process is completed when the r and k converge in the LSF procedure.

### A. Overview of Aging Simulation Method for a Transistor Dynamically Stressed During Operation

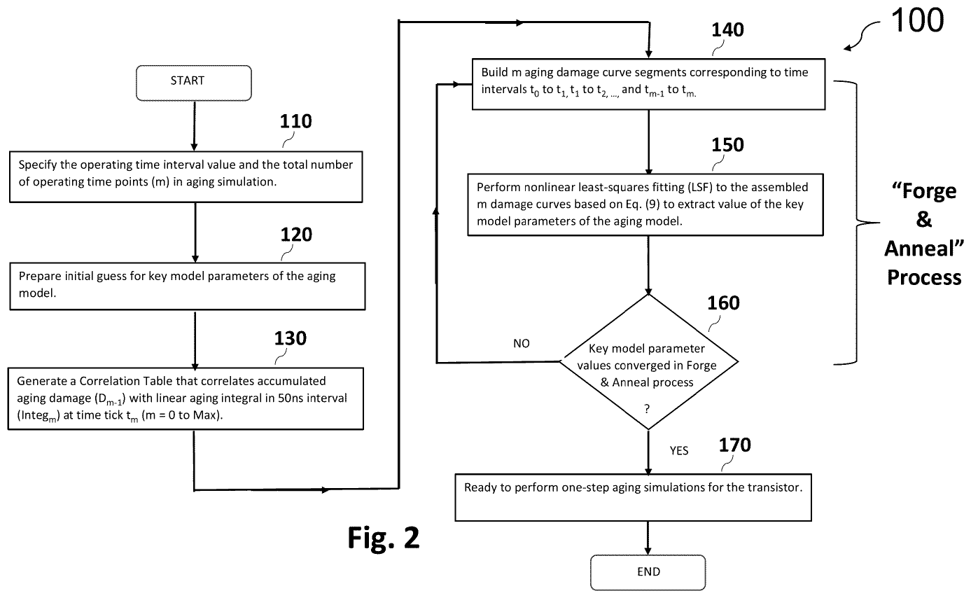

FIG. 2 is the flowchart 100 describing the method of aging simulation for a dynamically-stressed transistor during its operation. The flow starts with step 110 which specifies a standard time interval value, Δt, and the accompanying number of data point, N, for transistor aging simulation.

The next is step 120 which generates a gross estimate of the transistor aging damage versus operating time, Dₙ, tₙ), with a linear aging integral, Integₙ, in a very short time duration of (tₙ₋₁, tₙ₋₁+50 ns), n=1, 2, 3, . . . , m along with a linear extrapolation of Integₙ at t=tₙ₋₁+50 ns to Dₙ at t=tₙ. Here 50 ns is chosen for the very short time duration. Various meaningful values can be selected depending on the performance of a circuit design. The gross estimate of aging damage versus time, through a least-squares fit procedure, will provide initial guess of the initial aging rate (r) and the saturated aging damage (k) to jump-start the “Forge & Anneal” process.

The above is followed by step 130 which creates a correlation table that reflects accumulated transistor aging damage to this damage induced transistor characteristics change. This is accomplished by using the just-generated estimate of aging damage versus time where Dₙ₋₁ is mapped to Integₙ to constitute (Dₙ₋₁, Integₙ) pairs, n=1, 2, 3, . . . , m. The correlation table here will also be used during the “Forge & Anneal” process.

In the next, the “Forge & Anneal” process is performed. Steps 140, 150 and 160 describe the process. In step 140, segments of transistor aging versus operating time are forged and built. In step 150, the forged segments are assembled and go through a nonlinear LSF procedure to extract the two key aging parameters, the initial aging rate (r) and the saturated aging damage (k) of the transistor. Step 160 checks whether the two key parameters in the current cycle of the “Forge & Anneal” process approach to the same values in the previous cycle. If not, the process is repeated until the convergence is reached.

When r and k converge, this concludes the extraction of the two key aging-behavior parameters of the transistor and the step 170, which is one-step aging simulations at any specified operating time, is ready to ensue for the transistor.

### B. Generation of the Correlation Table

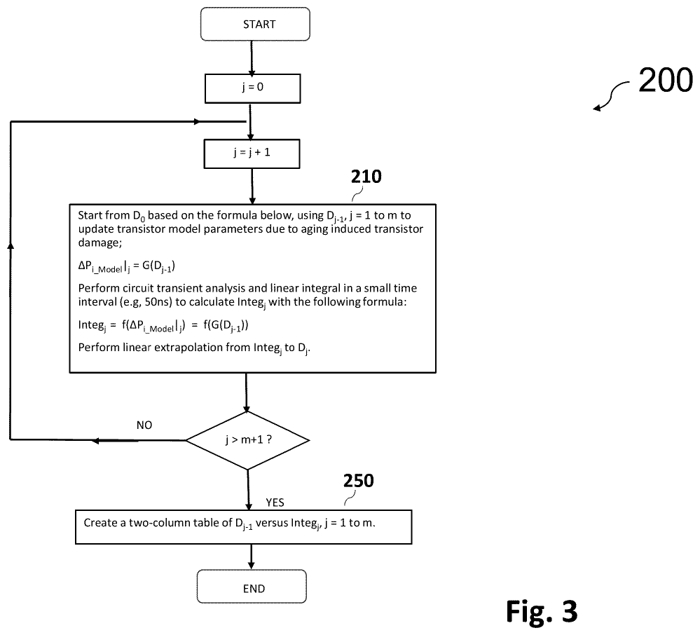

FIG. 3 is the flowchart 200 describing the process of creating a reference table that correlates the accumulated damage of a transistor to this damage induced transistor characteristics change and then the subsequent further damage to the transistor. Step 210 starts with damage D₀ based on the formula of ΔP_{i_Model}|ⱼ=G(Dⱼ₋₁), using Dⱼ₋₁, j=1 to m, to update transistor model parameters due to aging induced transistor damage. Circuit transient analysis, followed by a linear integral in a small time interval (e.g, 50 ns), is performed to calculate Integⱼ with the formula of Integⱼ=f(ΔP_{i_Model}|ⱼ)=f(G(Dⱼ₋₁)). A linear extrapolation from Integⱼ to Dⱼ is then performed to obtain transistor aging damage at time tⱼ for next damage-versus-operating-time segment. In step 250, the correlation table is built via mapping Dⱼ₋₁ to Integⱼ to form a table of (Dⱼ₋₁, Integⱼ) pairs, j=1, 2, 3, . . . , m.

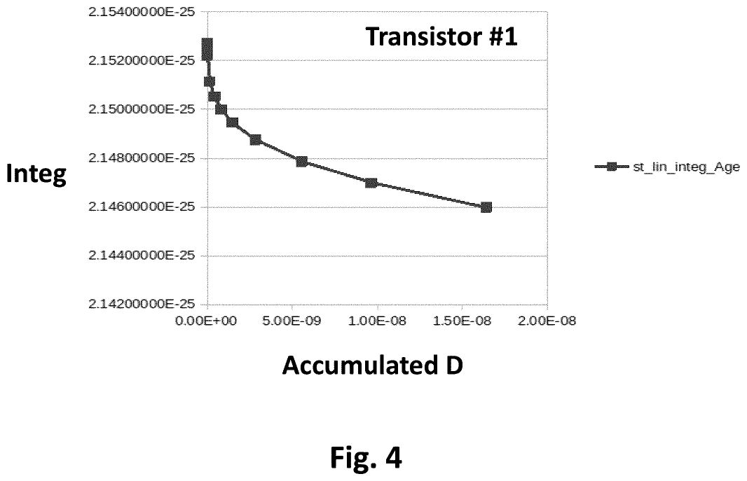

It is important to note that although the assembled (Dⱼ, tⱼ) of all segments represents an initial gross estimate for transistor aging damage versus operating time due to linear extrapolation being involved in its creation process, the correlation table here is by no means an estimate as the (Dⱼ₋₁, Integⱼ) pairs “exactly” reflect the effect from Dⱼ₋₁ based on the updated change of transistor model parameters caused by Dⱼ₋₁. As a result, this correlation table needs only to be generated once at beginning or even ahead of the aging simulation. This avoids repetitive circuit simulations to update transistor model parameters and compute Integ from D due to change of D value in each of the “Forge & Anneal” cycles. The correlation table here provides a means to quickly compute Integ from D with interpolation. The correlation table is one of the key elements contributing to the success of this invention. FIG. 4 shows a scatter plot of the elements in the Correlation Table used in obtaining Integⱼ, j=1 to m for a particular transistor case here.

### C. Forge and Anneal (One Transistor Case)

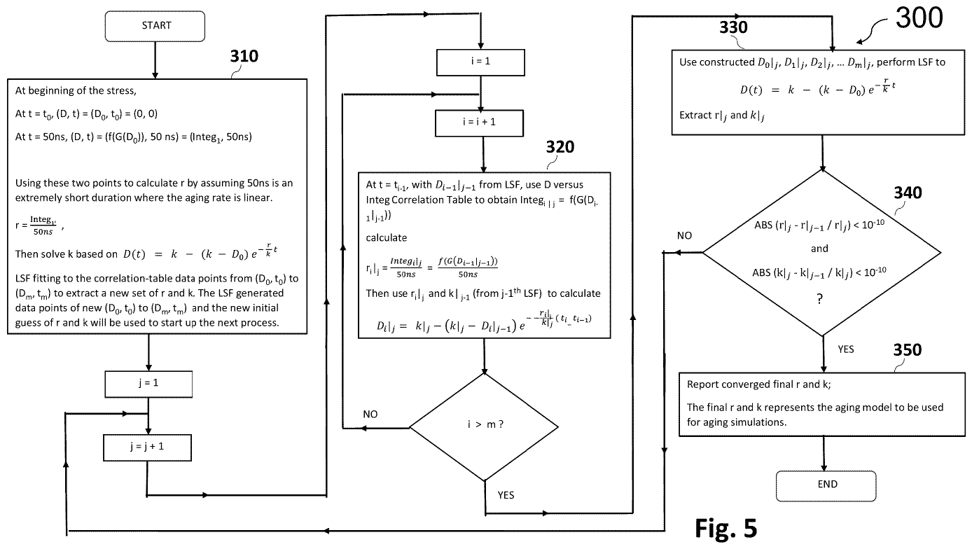

FIG. 5 is a flowchart 300 describing the “Forge & Anneal” process. As aforementioned, at beginning before the process, a gross estimate for the transistor damage versus operating time is performed first which uses D₀ (In usual case, D₀ is assumed to be 0) to obtain ΔP_{i_Model} and then calculate the integration, Integ=f(ΔP_{i_Model}), for a very short duration (e.g., 50 ns), followed by a linear extrapolation from the short-term Integ damage to a long-term time scale. This is the initial data set prepared for “Forge & Anneal” process.

Step 310 describes the above process. Two data points, (0, t₀) and (Integ₁, 50 ns) are used to calculate

$$r = \frac{Integ 1}{50 ns} ,$$

assuming D₀=0 and t₀=0. Then solving k based on

$$D ( t ) = k - ( k - {D}_{0} ) {e}^{- \frac{r}{k} t} .$$

The obtained r and k are used as an initial guess in a nonlinear LSF process for the gross estimate of transistor aging damage versus operating time. The LSF fitting data will be used as the new data set of (D₀, t₀) to (Dₘ, tₘ) along with the newly LSF-extracted k as an initial guess to start up the next step.

Step 320 begins the Forge & Anneal process. For each segment of transistor damage versus operating time in duration of (tᵢ, tᵢ₊₁), use D versus Integ Correlation Table, via interpolation, to obtain Integᵢ=f(G(Dᵢ₋₁)) at tᵢ, i=1, 2, 3, . . . , m. This is followed by calculating

$${r}_{i} = \frac{{Integ}_{i}}{50 ns} .$$

Using r₁ here and the k obtained in the previous step (310) to calculate a new data set of transistor damage versus operating time based on

$${D}_{i} = k - ( k - {D}_{i - 1} ) {e}^{- - \frac{{r}_{i}}{k} ( {t}_{i} - {t}_{i - 1} )} ,$$

i=1, 2, 3, . . . , m, for each of the damage-versus-time segments. In step 330, Nonlinear LSF is performed on this new data set to extract new r and k, based on

$$D ( t ) = k - ( k - {D}_{0} ) {e}^{- \frac{r}{k} t} .$$

Step 340 describes that the steps 320 & 330 cycle is repeated until both r and k converge. The convergence criterion is error <1e-10 in this “Forge & Anneal” process. The convergence criterion in the LSF procedure to “anneal” and produce new data set of transistor damage versus time inside the “Forge & Anneal” process is also error <1e-10. In step 350, the final r and k are reported and ready to be used in aging simulation. The final r and k value here determine the behavior of this transistor during the one-step transistor aging simulation at any operating time point.

The “Forge & Anneal” Technique is the spirit of this invention. The word of “Forge” means the building of the segments of the damage curves from time intervals of t₀ to t₁, t₁ to t₂, . . . , and tₘ₋₁ to tₘ. Note that as detailed in the flowchart 300 of FIG. 5, the initial aging rate, r, in each of the damage curve segments is different as it is calculated based on the accumulated damage of their previous segment respectively. The steady-state damage, k, in each of the damage curve segments in the current “Forge & Anneal” cycle is the same. But it is different between different “Forge & Anneal” cycles. It is derived from the LSF result (i.e., during annealing) from the previous “Forge & Anneal” iteration cycle. The accumulated transistor-aging induced damage effect is accounted for inside the calculated initial aging rate in each of the built damage curve segment. Such accumulated aging effect is also accounted for in the updated steady-state aging damage in each “Forge & Anneal” cycle. Equivalently, one can say that the accumulated aging induced transistor aging effect is taken into account by initial aging rate in “Forge” process and by steady-state aging in “Anneal” process. The iterated evolution by the “Forge & Anneal” process naturally and gradually leads the initial aging rate as well as the steady-state aging damage to their final rest state when the two parameters converge. This is where and how this invented aging simulation method is able to solve the decades-long inaccuracy and confidence problem in transistor and circuit aging simulations.

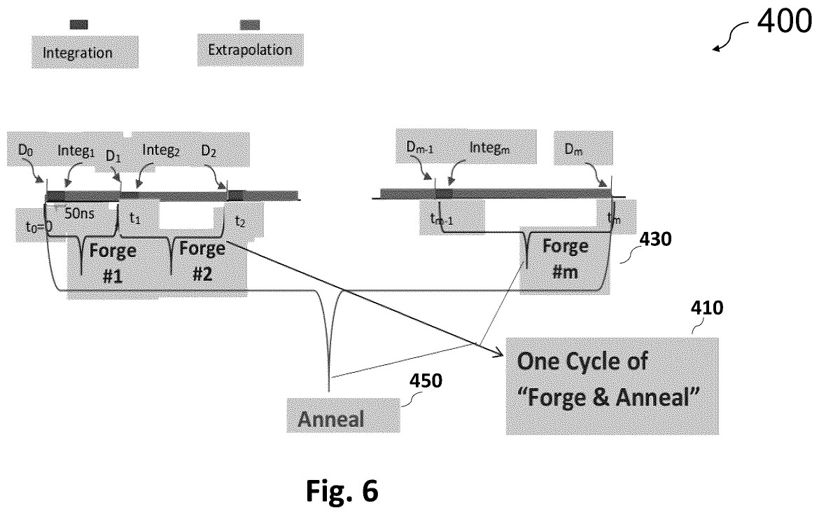

FIG. 6, in the form of illustration 400, shows the “Forge & Anneal” process in terms of time line chart. Step 410 shows that one cycle of the “Forge & Anneal” process comprises two steps, step 430 and step 450. Step 430 shows the Forge process where each of the m damage curve segments is forged (i.e., built) in which the accumulated transistor-aging induced damage effect is incorporated. Step 450 shows the Anneal process where annealing (i.e., in the form of nonlinear least-squares fitting) is performed on the assembled m segments. This annealing step reforms the initial aging rate and the steady-state aging by letting the two fundamental parameters freely go during LSF procedure without constraint. The two parameters eventually settle into their final rest state.

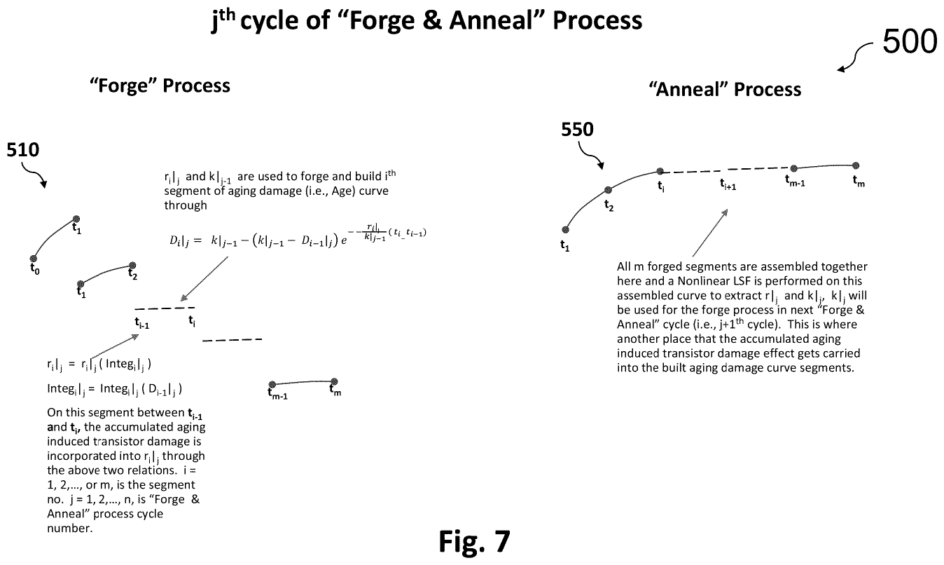

FIG. 7, in the form of illustration 500, shows the “Forge & Anneal” process in terms of segments and a whole of accumulated aging damage (or Age) versus stress time. “Forge” process (Step 510) and “Anneal” process (Step 550) are illustrated respectively. “Forge” process is performed in each of the transistor aging damage versus operating time segments. “Anneal” process is performed on the assembled forged-already segments. The accumulated aging induced transistor damage effect via transistor characteristics change is carried into all aging damage segments through the “Forge & Anneal” process.

Demonstration Result from Implementation

The invented aging simulation method has been implemented. The following are the result demonstrated from the implementation. A circuit with ten transistors is used here. One transistor is selected first to show how this invented aging simulation method works. A circuit simulator equipped with an appropriate transistor spice model with aging mechanism is used to simulate the response of the circuit under a bias setup arranged in the circuit netlist file. The nodal current and voltage of the selected transistor are simulated via 50-ns transient analyses. “Age” or stress damage is computed using the industrial commonly-used formula below:

$$Age {\vert}_{NMOS} = {\int }_{0}^{T} \frac{{I}_{ds}}{W {H}_{s}} {( \frac{{I}_{sub}}{{I}_{ds}} )}^{{m}_{s}} dt \qquad ( 13 )$$

$$Age {\vert}_{PMOS} = {\int }_{0}^{T} \frac{{I}_{ds}}{{H}_{g}} {( \frac{{I}_{g}}{W} )}^{{m}_{g}} dt \qquad ( 14 )$$

For convenience, the computed “Age” here shall be called “Damage” and denoted with a symbol of D. In the next, a “Damage curve” of this transistor over the time under the stress of circuit operation will be constructed. Since there is no stress before the circuit is operated, D=D₀=0 at t=t₀=0. The 50-ns dc transient produces a Damage, Integ₁, at t=50 ns. Using the two data points, one can extend the Damage curve to t=t₁ with linear extrapolation. This gives rise to D=D₁ at t₁. Again one can then compute Integ₂ using D₁. By repeating the above process, a Damage curve is constructed via the Damages calculated at t=t₀ to tₘ. This constructed Damage curve serves as an initial damage estimate created before the invented aging simulation method is used. Since there is not yet a realistic Damage curve generated from this simulation method, this initial Damage curve is one that can be best possibly produced at beginning. From here on, the proposed aging simulation method, once applied, will begin to transform the Damage curve gradually into a reliable and trusted one.

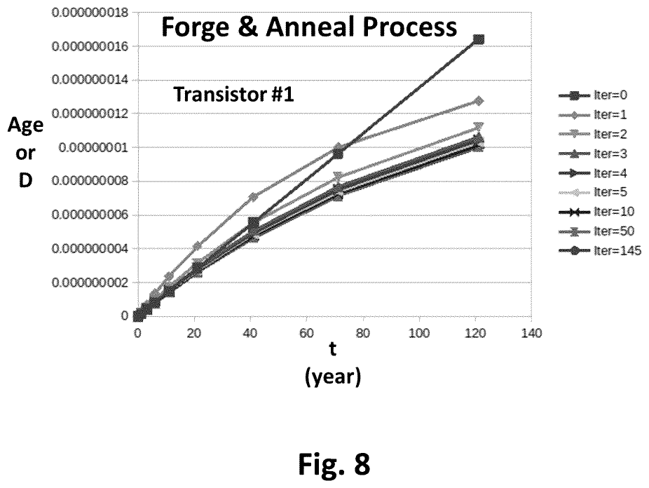

FIG. 8 shows the evolution of the Damage curve during “Forge & Anneal” process on one transistor. The curve transforms from the initial one created before the circuit aging simulation starts (process iteration #=0) to the final converged one after aging simulation ensues. The transformation begins rapidly in the first few “Forge & Anneal” iterations (i.e., cycles). The change slows down and saturates eventually when extracted r and k do not change their values any more (process iteration #=145) where both r and k values in “Forge & Anneal” process converges under a tolerance of accuracy criterion of 10⁻¹⁰.

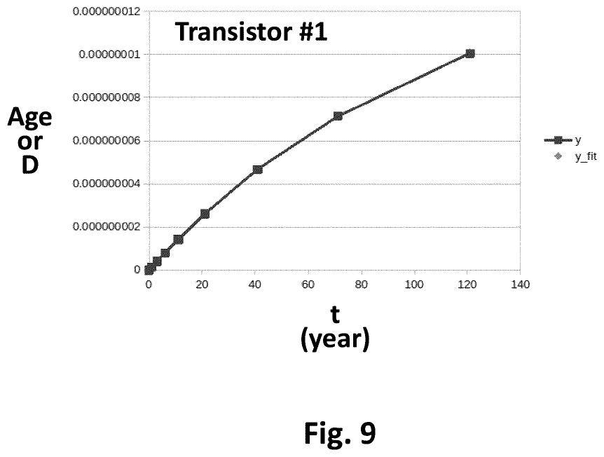

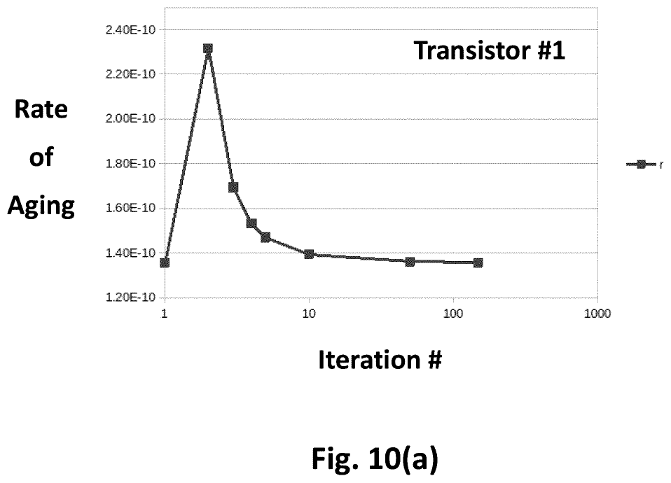

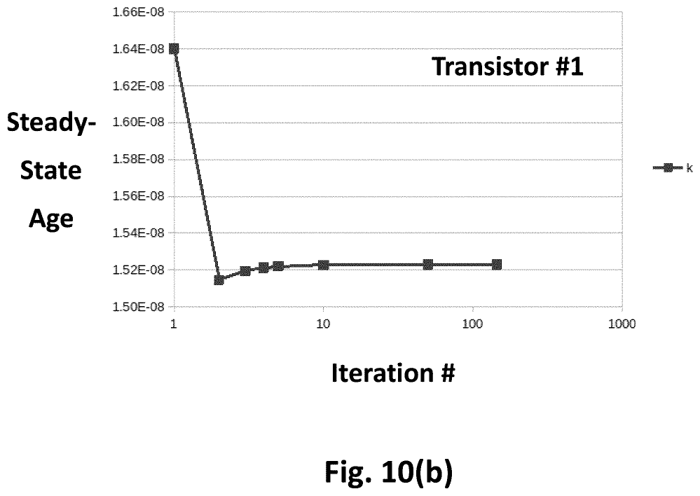

FIG. 9 is the nonlinear least-squares fitting result in one of the “Forge & Anneal” iteration cycles on the transistor, showing excellent fitting. FIGS. 10(a) and 10(b) shows how r and k evolve during “Forge & Anneal” process. The first data point at t=t₀=0, corresponding to initial guess of r and k at right beginning of the “Forge & Anneal” process, shows that both parameters are quite off from the correct trend. The figure shows that r and k are set back to the right track of the trend very quickly in the second iteration of the “Forge & Anneal” process. Both parameters eventually saturate to final values.

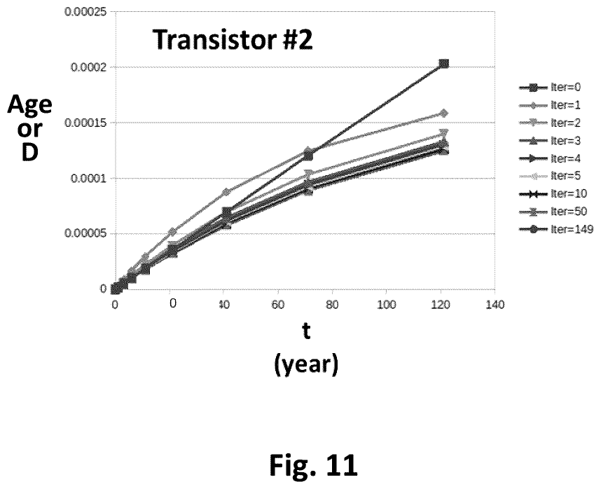

The above implementation is also successfully applied to all other nine transistors in the circuit. FIG. 11 demonstrates the evolution of the Damage curve on one of these other nine transistors during “Forge & Anneal” process. Note that this transistor has much higher Age or aging damage comparing with the transistor referred in FIG. 8.

The aging mechanisms and models developed earlier for transistors have been widely used in industry, as shown in those commercial circuit simulation tools. However, applying them in circuit aging simulation for a long-term time scale would inevitably invite accuracy issue in the result. The reason is that spending a moderate amount of time to accomplish such simulation in a scale of long-term period would require a short-cut approach to shorten simulation time. Theoretically, updating transistor characteristics very often at every of extremely small time intervals to reflect the accumulated aging damage induced transistor damage would render more accurate aging simulation result. Unfortunately, such practice would make simulation time extremely long, expensive and thus unacceptable. This trade-off between accuracy and simulation time in aging simulation has been a tough problem in the industry. This is not easy to be solved unless a breakthrough via an ingenious way can be made somehow.

The invented aging simulation method here presents an innovation that breaks through the traditional thinking in tackling this decades-long problem. An aging model developed in this invention is the carrier such that a successful solution to the above problem can be achieved. This aging model, described in Eq. (9) or Eqs. (10)-(12), is different from Eqs. (13) and (14) that describe transistor aging mechanism. Rather, it is a model modeling the result obtained from aging damage calculated based on Eqs. (13) and (14). Yet it also takes into account the accumulated transistor-aging induced damage effect. This aging model collaborates with the spirit of this invented aging simulation method, the “Forge & Anneal” technique, so that successful tasks can be achieved. The developed aging model here is in simplest and pristine form based on Eqs. (4)-(7) with only two parameters, the initial aging rate at the beginning and the final saturated state of aging damage at time infinity. The model parameter values are determined in a way of natural evolution to their final rest state during the “Forge & Anneal” process. Such nature inherited model is essential to the success of this invention.

One may realize by thinking deeper that the philosophy behind the invented new transistor and circuit aging simulation methodology is that if one is to replace the existing multiple-step aging simulation methodology to a one-step methodology, then one has to incorporate the interaction between the accumulated aging-induced transistor damage and the transistor characteristics change into the one-step aging simulation. One has to introduce another “medium” to assist. To lift the problem one dimension higher allows one to see more clearly the problem. The “Forge & Anneal” technique is such third dimension which works with the existing dimensions to show a way that transistor and circuit aging simulation result can be reliable and confidently trusted. In this “Forge & Anneal” technique, the confidence and trust of the result lie in the “converge” of the final aging damage versus stress time curves. Nevertheless, the nature-manifested general aging model developed here serves an immensely important role as well in the success of the new methodology here.

It is also important to note the role of the initial (i.e., the very first) Damage curve generated with linear extrapolation from the 50 ns-duration linearly-integrated aging damage. There are two purposes to have this initial Damage curve. First, this data in conjunction with their corresponding 50 ns-duration linearly-integrated aging damage are used to produce the Correlation Table which is used to facilitate the calculation of Integᵢ, i=1 to m, in each iteration cycle of the “Forge & Anneal” process. Second, the data are used in a LSF procedure before the “Forge & Anneal” process to extract a rough initial aging rate and steady-state aging damage to serve as an initial guess for the upcoming “Forge & Anneal” process. Fairly to say, this jumpstarts the “Forge & Anneal” process.

The success of the demonstration for this invention indicates that the multiple-step circuit aging simulation methodology used in the industry can be replaced with a one-step one. This is because the converged Damage curve, with the converged final r and k, at the end of “Forge & Anneal” process has already incorporated the accumulated aging induced transistor damage effect to itself. The one-step circuit aging simulation here enables directly to simulate transistor and circuit aging damage at any operating time point.

The “Forge & Anneal” technique disclosed here may be implemented in other fields that involve events of stress, wear-out, etc., besides in the field of electronics. These other fields include, but not limited to, thermal, mechanical, chemical or materials field.

Although specific embodiments have been illustrated and described herein for purposes of description, it will be appreciated by those of ordinary skill in the art that a wide variety of alternate and/or equivalent implementations calculated to achieve the same purposes may be substituted for the specific embodiment shown and described without departing from the scope of the present invention. Those with skill in the art will readily appreciate that the present invention may be implemented in a very wide variety of embodiments. This application is intended to cover any adaptations or variations of the embodiments discussed herein.

What is claimed is:

1. A computer method of estimating an aging damage of a transistor, in a one-step procedure, at a specified operating time during a chip operation, comprising:
implementing a mechanism wherein the transistor follows its naturally-inherited behavior of initial and final state of aging;
generating a gross estimate of a chip operation induced aging damage on the transistor over a long period of chip operation time;
setting up a correlation table between the chip operation induced aging damage and the subsequent transistor-characteristics-change induced aging damage calculated in a pre-determined tens-nanosecond-range duration; and
enforcing a forge and anneal technique to the gross estimate of transistor aging damage versus operating time;
using the final-converged initial aging rate and saturated damage extracted by the forge and anneal technique to compute aging damage of the transistor at the specified operating time; and
updating model parameters of the transistor and simulating circuit response at the specified operating time.

2. The computer method according to claim 1, wherein the one-step procedure enables the method, at any specified operating time, to estimate transistor aging damage taking into account accumulated aging induced effect on a dynamically stressed transistor without going through the traditional multiple-step estimate procedure.

3. The computer method according to claim 1, wherein the mechanism observed by the transistor further comprising a linear aging rate at the beginning and a saturated damage at the end of a long chip operation time.

4. The computer method according to claim 1, wherein the grossly estimated aging damage over a long period of chip operation time further comprising a pre-determined limited number of chip operation time points and a linear extrapolation of aging damage in a pre-determined tens-nanosecond-range duration to aging damage in a long-time duration between two adjacent chip operating time points.

5. The computer method according to claim 1, wherein the forge and anneal technique further comprising
performing a nonlinear-least-square fit to the gross estimate of the chip operation induced aging damage versus operating time to extract the final saturated damage for use in the forge and anneal process; and
performing a repeated forge and anneal process to extract final converged initial aging rate and saturated damage.

6. The forge and anneal technique according to claim 5, wherein the forge and anneal process further comprising
computing an initial aging rate in the pre-determined tens-nanosecond-range duration using the correlation table at the current operating time point, and computing transistor aging damage using the computed initial aging rate and the saturated damage obtained at the previous cycle of the repeated forge and anneal process;
repeating the above process for next designated operating time point till the last time point to create a curve of transistor aging damage versus operating time; and
performing the nonlinear-least-square fit to the generated curve of transistor aging damage versus operating time to obtain settled initial aging rate and saturated damage.

7. The forge and anneal technique according to claim 5, wherein the repeated forge and anneal process iterates the forge and anneal process until the settled initial aging rate and saturated damage in current and previous iteration converge to same values within a pre-determined error tolerance.
